(19) United States
(12) Patent Application Publication
(10) Pub. No.: US 2008/0252291 A1
(43) Pub. Date: Oct. 16, 2008

(54) High Angular Resolution Diffusion Weighted Mri

(75) Inventors: Frank Gerardus Cornelis Hoogenraad, Eindhoven (NL); Ronaldus Frederik Johannes Holthuizen, Eindhoven (NL); Robert Brijder, Oosterhout (NL)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N.V., Eindhoven (NL)

(21) Appl. No.: 10/597,570

(22) PCT Filed: Jan. 31, 2005
(86) PCT No.: PCT/IB05/50402

§ 371 Date: Jul. 31, 2006

(30) Foreign Application Priority Data
Feb. 6, 2004 (EP) 04100442.5

(51) Int. Cl. G01R 33/563

(52) U.S. Cl. 324/309

(57) ABSTRACT

A magnetic resonance imaging method involves acquisition of magnetic resonance signals with application of diffusion weighting at a plurality of diffusion weighting strengths diffusion directions. An object dataset is reconstructed from the magnetic resonance signals in which apparent diffusion coefficients are assigned. The occurrence of one single or several diffusion directions in identified for individual voxels. In this way account is taken of crossing fibres.

The invention pertains to an angular resolved diffusion weighted magnetic resonance imaging method. In angular resolved diffusion magnetic resonance imaging method, magnetic resonance signals are acquired that are diffusion weighted. The diffusion weighting is effected by way of diffusion magnetic gradient fields. These diffusion weighted magnetic resonance signals are also spatially encoded by way of encoding magnetic gradient fields such as read gradient fields and phase encoding gradients. In particular in diffusion tensor imaging (DTI), diffusion weighting is performed for several spatial directions. From the diffusion weighted magnetic resonance signals and on the basis of a tensor analysis, local principal diffusion directions are derived for individual voxels. The diffusion process is a stochastic process of the population of nuclear (proton) spins and the tensor analysis derives the main diffusion directions into which the diffusive motion of the individual spins. These main directions correspond to the directions of the eigenvectors of the diffusion tensor and the main direction relating to the largest eigenvalue is the principal diffusion direction. This principal diffusion direction represents the direction in which diffusion mainly takes place in the voxel at issue. Information of diffusion directions and the apparent diffusion coefficients is useful to extract the directional fibre structure in neurological systems such as the human or animal brain and spinal cord.

Angular resolved diffusion magnetic resonance imaging is known from the paper ‘Characterization of anisotropy in high angular resolution diffusion-weighted MRI’ by L. R. Frank in MRM47 (2002)1083-1099.

The cited paper mentions the problem that multiple principal diffusion directions may appear in a single voxel and that characterisation of diffusion in such voxels becomes problematic. The known magnetic resonance imaging method applies methods of group theory to this problem to show that the measurements can be decomposed into irreducible representations of the rotation group in which isotropic, single fibre, multiple fibre components are separable direct sum subspaces. Multiple fibres passing through a single voxel are represented in a decomposition based on spherical harmonics and the state of a voxel with several fibres passing through it can be expressed as a direct sum of irreducible representations of the rotation group.

An object of the invention is to provide a high angular resolution diffusion-weighted magnetic resonance imaging method which requires less computational effort than the known magnetic resonance imaging method.

This object is achieved by the magnetic resonance imaging method of the invention comprising
acquisition of magnetic resonance signals including application of diffusion weighting and involving a plurality of diffusion weighting strengths and a plurality of diffusion directions
reconstruction of an object dataset from the magnetic resonance signals
the object dataset assigning apparent diffusion coefficients to voxels in a multidimensional geometric space and
identifying the occurrence of a single or several diffusion directions in individual voxels of the object dataset.

According to the invention contributions from different principal diffusion directions (fibre directions) in individual voxels are distinguished on the basis of diffusion weighted magnetic resonance signals for several values of the diffusion weighting. The invention is based on the insight that the dependence of the signal level of the diffusion weighted magnetic resonance signals on the diffusion weighting is different in voxels where there is only one single principal diffusion direction as compared to voxels where there is a superposition of contributions from several principal diffusion directions. Even, the way the signal level of the diffusion weighted magnetic resonance signals depends on the applied diffusion weighting reflects the number of principal diffusion directions that occur in the voxel at issue. Hence, on the basis of a variation with the diffusion strength of the apparent diffusion coefficient voxels having a single diffusion direction are distinguished from voxels having several diffusion directions. That is, voxels through which fibres pass at different directions can be identified. Accordingly, in the further analysis of the object dataset account can be taken of voxels in which contributions of several principal diffusion directions occur. Notably, in these voxels a decomposition of contribution from the respective principal diffusion directions carried out.

These and other aspects of the invention will be further elaborated with reference to the embodiments defined in the dependent Claims.

From the magnetic resonance signals at several diffusion weightings, respective values of the apparent diffusion coefficients for individual voxels are computed. From these diffusion weighted dependent values, the contributions for separate principal diffusion directions can be computed for the voxel at issue. Hence, contributions to the apparent diffusion coefficient from various fibres passing through the voxel at issue are obtained. Accordingly, the local directional structure of fibres can be better resolved, even if several fibres are crossing at the voxel at issue.

It appears that in practice diffusion strengths for several principal diffusion directions do not vary substantially at the scale of an individual voxel. According to one aspect of the invention the apparent diffusion coefficient can be accurately decomposed into contributions to the respective identified principal diffusion directions. This decomposition can be made on the basis of the assumption that diffusion strengths are equal for the respective principal diffusion direction in the voxel at issue. This assumption appears often to be quite accurate, e.g. because an individual voxel usually pertains to a single type of tissue. This assumption substantially reduces the computational effort to compute the contributions to the apparent diffusion coefficient. The ultimate accuracy of the resolution of the local directional structure of the directional structure of the fibres is hardly affected.

The invention also pertains to a method of analysis of an object dataset as defined in claim 4. The method of analysis of an object dataset of the invention achieves to analyse the directional fibre structure separately from the acquisition of the magnetic resonance signals. That is, the patient can be scanned to acquired the magnetic resonance signal data and these data are later analysed to analyse the directional structure. This analysis can at option also be performed at a different location.

The invention also pertains to a computer programme as defined in claim 5. The computer programme of the invention can be installed in a general purpose workstation so as to enable the workstation to perform the method of analysis of the object dataset of the invention. This workstation may be separate from the magnetic resonance imaging system which acquires the diffusion weighted magnetic resonance signals.

The invention further relates to an magnetic resonance imaging system as defined in claim 6. The magnetic resonance imaging system of the invention comprises an image processing unit which carries out the method of the invention. Notably, in the image processing unit the computer programme of the invention is installed.

These and other aspects of the invention will be elucidated with reference to the embodiments described hereinafter and with reference to the accompanying drawing wherein

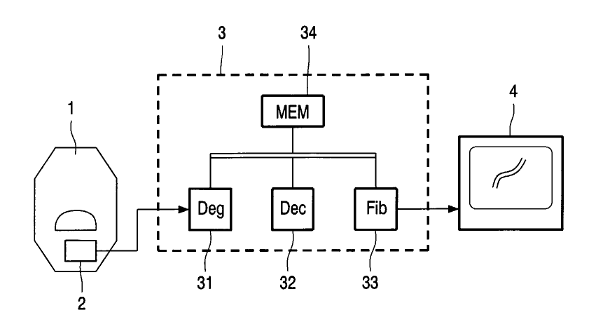

FIG. 1 shows a schematic representation of an magnetic resonance imaging system in which the invention is employed.

FIG. 1 shows a schematic representation of an magnetic resonance imaging system in which the invention is employed. The magnetic resonance imaging system comprises an MR-imager 1 which includes a main magnet to generate a stationary magnetic field, a gradient system to apply magnetic gradient fields to spatially encode magnetic resonance signals and an RF-system is provided to generate and receive magnetic resonance signals. Further, the MR-imager 1 incorporates a reconstruction unit which forms an object dataset from the magnetic resonance signals. In particular, the MR-imager is operated to generate diffusion-weighted magnetic resonance signals. Diffusion weighting in magnetic resonance imaging, is generally performed by applying a diffusion sensitive pulse sequence of magnetic gradient fields and RF-pulses. For example a bipolar gradient wave form may be used or diffusion sensitising gradient pulses having the same polarity and separated by a refocusing RF-pulse can be used. From the diffusion-weighted magnetic resonance signals the object dataset is reconstructed. This object dataset assigns values of the apparent diffusion coefficient to voxels, generally in a geometric volume. That is, to voxel-positions in three-dimensional space, there are allocated the value of the apparent diffusion coefficient for that voxel-position. This object dataset is applied to an image processing unit 3 and stored in a memory unit 34. In the object dataset apparent diffusion coefficients are provided for several values of the diffusion strength. By a degeneracy check 31 for individual voxels variation of the apparent diffusion coefficient with the diffusion strength is identified. The degeneracy check 31 identifies voxels in which there are contributions due to different principal diffusion directions, i.e. through which apparently various fibres cross. For these identified voxels in which several diffusion direction occur, a decomposition 32 decomposes the apparent diffusion coefficient into its components for these principal diffusion directions identified in the voxel at issue. A fibre tracking 33 is then applied to the object dataset so as to identify directional structures in the object dataset. Such directional structures or fibres, are voxels that are connected along directions of the diffusion directions in these voxels. The present invention allows identification of crossing of fibres in voxels. Accordingly, the image processing unit applies the identified directional structures to a viewing station 4. On the viewing station the fibre structure is displayed.

The degeneracy check 31 and the decomposition 32 of the apparent diffusion coefficient into components for the respective principal diffusion directions is based on the following considerations. In general the measured magnetic resonance signal intensity in multi-fibre situation is given as:

$$S ( v ) = {S}_{0} {\sum }_{k} {f}_{k} {e}^{- bv \cdot {D}_{k} \cdot v}$$

Here S(v) is the measured signal at voxel position v, S₀ is the measured signal when no diffusion sensitation is applied, Dₖ is the 3×3 diffusion matrix for the k-th fibre, b represents the diffusion strength of the diffusion sensitive pulse sequence and fₖ is the volume fraction of the k-th fibre in that voxel. Because several measurement are made for b-values and diffusion directions, the quantities Dₖ and fₖ can be obtained, e.g. on the basis of a model fitting method.

1. A magnetic resonance imaging method comprising
acquisition of magnetic resonance signals including application of diffusion weighting and involving a plurality of diffusion weighting strengths and a plurality of diffusion directions
reconstruction of an object dataset from the magnetic resonance signals
the object dataset assigning apparent diffusion coefficients to voxels in a multidimensional geometric space and
identifying the occurrence of a single or several diffusion directions in individual voxels of the object dataset.

2. A magnetic resonance imaging method as claimed in claim 1, wherein the apparent diffusion coefficients for individual voxels are decomposed into contributions for the respective diffusion direction(s) for the voxel at issue.

3. A magnetic resonance imaging method as claimed in claim 2, wherein the decomposition of the apparent diffusion coefficients is done on the basis of equal diffusion strengths for the identified principal diffusion directions in the voxel at issue.

4. A method of analysis of an object dataset assigning apparent diffusion coefficients to voxels in a multidimensional geometric space, the analysis comprising identifying the occurrence of a single or several diffusion directions in individual voxels of the object dataset from a plurality of diffusion weighting strengths and a plurality of diffusion directions for individual voxels.

5. A computer program for analysis of an object dataset assigning apparent diffusion coefficients to voxels in a multidimensional geometric space, the computer program comprising instructions to identify the occurrence of a single or several diffusion directions in individual voxels of the object dataset from a plurality of diffusion weighting strengths and a plurality of diffusion directions for individual voxels.

6. A magnetic resonance imaging system arranged to
acquisition of magnetic resonance signals including application of diffusion weighting and involving a plurality of diffusion weighting strengths and a plurality of diffusion directions
reconstruction of an object dataset from the magnetic resonance signals
the object dataset assigning apparent diffusion coefficients to voxels in a multidimensional geometric space and the magnetic resonance imaging system including an image processing unit to
identify the occurrence of a single or several diffusion directions in individual voxels of the object dataset.
